(19) United States
(12) Patent Application Publication
(10) Pub. No.: US 2011/0171758 A1
(43) Pub. Date: Jul. 14, 2011

(54) RECLAMATION OF SCRAP MATERIALS FOR LED MANUFACTURING

(75) Inventors: JIE SU, Santa Clara, CA (US); OLGA KRYLIOUK, Sunnyvale, CA (US)

(73) Assignee: APPLIED MATERIALS, INC., Santa Clara, CA (US)

(21) Appl. No.: 12/985,839

(22) Filed: Jan. 6, 2011

Related U.S. Application Data
(60) Provisional application No. 61/293,462, filed on Jan. 8, 2010.

(51) Int. Cl. H01L 21/66; H01L 21/465; H01L 21/36

(52) U.S. Cl. 438/5; 156/345.24; 257/E21.521; 257/E21.04

(57) ABSTRACT

A method for reclamation of scrap materials during the formation of Group III-V materials by metal-organic chemical vapor deposition (MOCVD) processes and/or hydride vapor phase epitaxial (HVPE) processes is provided. More specifically, embodiments described herein generally relate to methods for repairing or replacing defective films or layers during the formation of devices formed by these materials. By periodic testing of the layers during the formation process, low-quality layers that may result in low-quality or defective devices may be detected prior to completion of the device. These low-quality layers may be partially or completely removed and redeposited to reclaim the substrate and any remaining high-quality layers that were previously deposited under the low-quality layer.

### CROSS-REFERENCE TO RELATED APPLICATIONS

This application claims benefit of U.S. provisional patent application Ser. No. 61/293,462, filed Jan. 8, 2010, which is herein incorporated by reference.

### BACKGROUND OF THE INVENTION

1. Field of the Invention

Embodiments of the present invention generally relate to the manufacturing of devices, such as light emitting diodes (LED's), laser diodes (LD's) and, more particularly, to processes for reclamation of scrap materials during the manufacturing processes.

2. Description of the Related Art

Group III-V films are finding greater importance in the development and fabrication of a variety of semiconductor devices, such as short wavelength LED's, LD's, and other electronic devices including high power, high frequency, high temperature transistors and integrated circuits. For example, short wavelength (e.g., blue/green to ultraviolet) LED's are fabricated using the Group III-nitride semiconducting material gallium nitride (GaN). It has been observed that short wavelength LED's fabricated using GaN can provide significantly greater efficiencies and longer operating lifetimes than short wavelength LED's fabricated using non-nitride semiconducting materials, comprising Group II-VI elements.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface. The quality of the film depends in part upon deposition uniformity which, in turn, depends upon uniform flow and mixing of the precursors across the substrate.

In some cases, the quality of the deposited films may not be adequate to form high quality or even operational devices, resulting in the loss of the substrates. In many cases these substrates are expensive, being made of sapphire, and in some cases being formed with features thereon that represent a significant investment by the fabricator.

As the demand for LED's, LD's, transistors, and integrated circuits increases, the efficiency of depositing high quality Group-Ill nitride films takes on greater importance. Therefore, there is a need for an improved process and apparatus that can repair and/or replace low-quality films or otherwise recycle substrates to increase the efficiency of producing the end products.

### SUMMARY OF THE INVENTION

Embodiments of the invention generally relate to methods and apparatus for forming Group III-V materials by metal-organic chemical vapor deposition (MOCVD) processes and hydride vapor phase epitaxial (HVPE) processes. More specifically, the methods and apparatus of the present invention provide for removing and replacing defective layers or films of these materials prior to completion of the desired devices.

In one embodiment, a method for fabricating a compound nitride semiconductor structure within desired parameters comprises depositing a first group-III nitride layer over one or more substrates within a first processing chamber, testing the first group-III nitride layer to determine whether the first group-III nitride layer is within the desired parameters, removing at least a portion of the first group-III nitride layer if the first layer is not within the desired parameters, and depositing an additional first group-III nitride layer to replace the removed portion of the first group-III nitride layer.

In another embodiment, a method for fabricating a compound nitride semiconductor structure within desired parameters comprises depositing a first GaN layer over the one or more substrates within the first processing chamber, testing the first GaN layer within the first processing chamber to determine whether the first GaN layer is within the desired parameters, removing at least a portion of the first GaN layer if the first GaN layer is not within the desired parameters, depositing an additional first GaN layer to replace the removed portion of the first GaN layer within the first processing chamber, depositing an InGaN layer over the one or more substrates within a second processing chamber, testing the InGaN layer within the second processing chamber to determine if the second layer is within the desired parameters, removing at least a portion of the InGaN layer if the InGaN layer is not within the desired parameters, and depositing an additional InGaN layer to replace the removed portion of the InGaN layer within the second processing chamber.

In yet another embodiment, an apparatus for fabricating a compound nitride semiconductor structure comprises a processing chamber, at least one metrology tool, and a system controller. The processing chamber comprises a chamber body enclosing a processing volume, a substrate support for supporting one or more substrates proximate the processing volume, a precursor source for depositing at least one layer on the one or more substrates, and an etching source for removing defective portions of the at least one layer. The metrology tool is configured for detecting the defective portions of the at least one layer. The system controller is configured to receive data from the at least one metrology tool, control the etching source to remove the defective portions of the at least one layer, and control the precursor source for depositing an additional layer to replace the removed portions of the at least one layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a structure of a GaN-based LED.

FIG. 2 is a schematic top view illustrating one embodiment of a processing system for fabricating compound nitride semiconductor devices.

FIG. 3 is a schematic cross-sectional view of a metal-organic chemical vapor deposition (MOCVD) chamber for fabricating compound nitride semiconductor devices according to embodiments described herein.

FIG. 4 is a schematic cross-sectional view of a hydride vapor phase epitaxy (HVPE) chamber for fabricating compound nitride semiconductor devices according to embodiments described herein.

FIGS. 5A-5F are schematic views illustrating a process for forming and repairing compound nitride semiconductor devices according to embodiments described herein.

FIGS. 6A-6B illustrate a flow diagram of a process that may be used for forming and/or repairing compound nitride semiconductor devices according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention generally relate to methods for repairing or replacing films or layers of Group III-V materials that may be formed by metal organic chemical vapor deposition (MOCVD) processes and/or hydride vapor phase epitaxial (HVPE) processes. By periodic testing of the layers during the formation process, low-quality layers that may result in low-quality or defective devices may be detected prior to completion of the device. These low-quality layers may be partially or completely removed, and redeposited to reclaim the substrate and any remaining high-quality layers that were previously deposited under the low-quality layer.

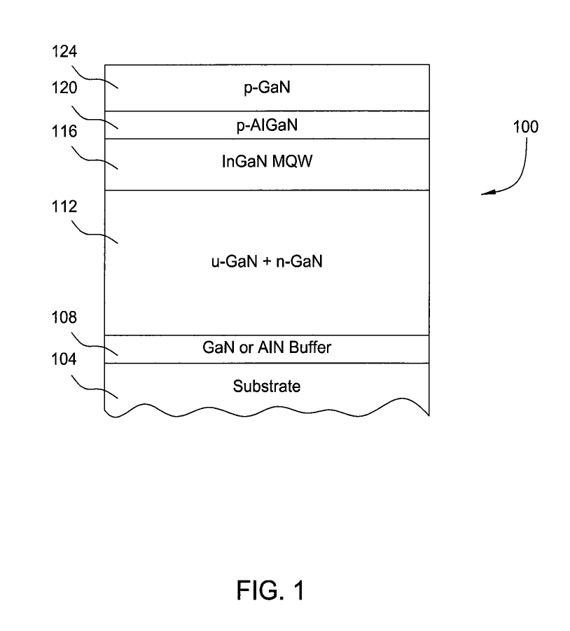

Currently, metal organic chemical vapor deposition (MOCVD) techniques are the most widely used techniques for the growth of Group III-nitride based LED manufacturing. An exemplary nitride-based structure is illustrated in FIG. 1 as a GaN-based LED structure 100. It is fabricated over a substrate 104. Exemplary substrates include sapphire, silicon, quartz, zinc oxide, magnesium oxide, and lithium aluminum oxide substrates. A u-GaN followed by an n-type GaN layer 112 is deposited over a GaN or aluminum nitride (AlN) buffer layer 108 formed over the substrate 104. An active region of the device is embodied in a multi-quantum-well layer 116, shown in FIG. 1 as an InGaN MQW layer. A p-n junction is formed with an overlying p-type AlGaN layer 120 and a p-type GaN layer 124 acting as a contact layer.

One example of a fabrication process for such an LED may use an MOCVD process that follows cleaning of the substrate 104 in a processing chamber. The MOCVD is accomplished by providing flows of suitable precursors to the processing chamber and using thermal processes to achieve deposition. For example, a GaN layer may be deposited using Ga and nitrogen containing precursors, which may be accompanied by a flow of a carrier gas like N₂, H₂, or NH₃. An InGaN layer may be deposited using Ga, N, and In precursors, which may be accompanied by a flow of a carrier gas as well. An AlGaN layer may be deposited using Ga, N, and Al precursors, which also may be accompanied by a flow of a carrier gas. The GaN buffer layer 108 may have a thickness of between about 200 Å and about 500 Å, and may have been deposited at a temperature of about 550° C. Subsequent deposition of the u-GaN and n-GaN layer 112 is typically performed at a higher temperature, such as around 1000° C. The u-GaN and n-GaN layer 112 may be relatively thick, with a deposition thickness on the order of 4 μm requiring about 140 minutes for deposition. The InGaN multi-quantum-well (MQW) layer 116 may have a thickness of about 750 Å, which may be deposited over a period of about 40 minutes at a temperature of about 750° C. The MQW layer 116 may include alternating GaN barrier layers (e.g., 3-20 nm thick) and InGaN quantum well layers (e.g., 1-3 nm thick) 1-20 times. The p-AlGaN layer 120 may have a thickness of between about 200 Å and about 500 Å, which may be deposited in about five minutes at a temperature from about 950° C. to about 1020° C. The p-AlGaN layer 120 serves as an electron blocking layer (EBL) to confine electrons in the active region and prevent electron overflow to the p-GaN layer. The thickness of the p-GaN or contact layer 124 that completes the structure may be between about 0.1 μm and about 0.5 μm, and may be deposited at a temperature of about 1020° C. for around 25 minutes. Additionally, dopants, such as silicon (Si) or magnesium (Mg), may be added to one or more of the films. The films may be doped by adding small amounts of dopant gases during the deposition process. For silicon, or n-type, doping, silane (SiH₄) or disilane (Si₂H₆) gases may be used. For magnesium, or p-type, doping Bis(cyclopentadienyl) magnesium (Cp₂Mg or (C₅H₅)₂Mg) gases may be used.

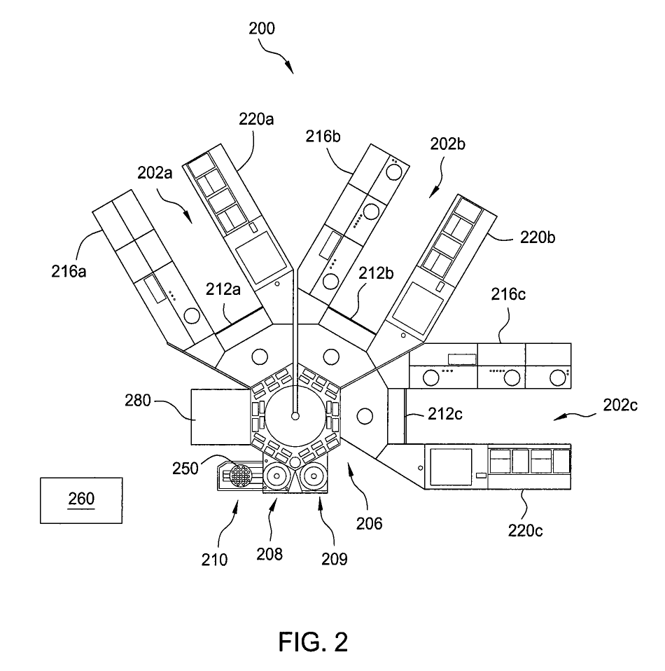

FIG. 2 is a schematic top view illustrating one embodiment of a processing system 200 suitable for fabricating compound nitride semiconductor devices according to embodiments of the invention. It is contemplated that the processes described herein may be also preformed in other suitably adapted processing chambers. The environment within the processing system 200 is maintained as a vacuum environment or at a pressure below atmospheric pressure. Additionally, it may be desirable to backfill the processing system 200 with an inert gas such as nitrogen.

The processing system 200 generally includes a transfer chamber 206 housing a substrate handler (not shown), a first MOCVD chamber 202a, a second MOCVD chamber 202b, and a third MOCVD chamber 202c coupled with the transfer chamber 206, a loadlock chamber 208 coupled with the transfer chamber 206, a batch loadlock chamber 209, for storing substrates, coupled with the transfer chamber 206, and a load station 210, for loading substrates, coupled with the loadlock chamber 208. The transfer chamber 206 includes a robot assembly (not shown) operable to pick up and transfer substrates between the loadlock chamber 208, the batch loadlock chamber 209, and the MOCVD chamber 202. Although three MOCVD chambers 202a, 202b, 202c are shown, it should be understood that any number of MOCVD chambers may be coupled with the transfer chamber 206. Additionally, chambers 202a, 202b, 202c may be combinations of one or more MOCVD chambers and one or more Hydride Vapor Phase Epitaxial (HVPE) chambers coupled with the transfer chamber 206.

Each MOCVD chamber 202a, 202b, 202c generally includes a chamber body 212a, 212b, 212c forming a processing region where a substrate is placed to undergo processing, a chemical delivery module 216a, 216b, 216c from which gas precursors are delivered to the chamber body 212a, 212b, 212c, and an electrical module 220a, 220b, 220c for each MOCVD chamber 202a, 202b, 202c that includes the electrical system for each MOCVD chamber of the processing system 200. Each MOCVD chamber 202a, 202b, 202c is adapted to perform CVD processes in which metal organic elements react with metal hydride elements to form thin layers of compound nitride semiconductor materials.

The transfer chamber 206 may be maintained under vacuum during processing. The vacuum level of the transfer chamber 206 may be adjusted to match the vacuum level of the MOCVD chamber 202a. For example, when transferring a substrate from the transfer chamber 206 into the MOCVD chamber 202a (or vice versa), the transfer chamber 206 and the MOCVD chamber 202a may be maintained at the same vacuum level. Then, when transferring a substrate from the transfer chamber 206 to the load lock chamber 208 or batch load lock chamber 209 (or vice versa), the transfer chamber vacuum level may match the vacuum level of the loadlock chamber 208 or batch load lock chamber 209 even though the vacuum level of the loadlock chamber 208 or batch load lock chamber 209 and the MOCVD chamber 202a may be different. Thus, the vacuum level of the transfer chamber 206 may be adjusted. It may be desirable to backfill the transfer chamber 206 with an inert gas such as nitrogen. For example, the substrate may be transferred in an environment having greater than 90% atomic N₂. In another example, the substrate is transferred in a high purity NH₃ environment, such as an environment having greater than 90% atomic NH₃. In yet another example, the substrate is transferred in a high purity H₂ environment, such as an environment having greater than 90% atomic H₂.

In the processing system 200, the robot assembly transfers a carrier plate 250 under vacuum loaded with substrates into the first MOCVD chamber 202a to undergo a first deposition process. The robot assembly transfers the carrier plate 250 under vacuum into the second MOCVD chamber 202b to undergo a second deposition process. The robot assembly transfers the carrier plate 250 under vacuum into either the first MOCVD chamber 202a or the third MOCVD chamber 202c to undergo a third deposition process. After all or some of the deposition steps have been completed, the carrier plate 250 is transferred from the MOCVD chamber 202a-202c back to the loadlock chamber 208. In one embodiment, the carrier plate 250 is then transferred to the load station 210. In another embodiment, the carrier plate 250 is stored in either the loadlock chamber 208 or the batch load lock chamber 209 prior to further processing in the MOCVD chamber 202a-202c. In one embodiment, the processing system 200 includes an etching chamber 280 for selectively etching substrates as subsequently described herein. One exemplary system is described in U.S. patent application Ser. No. 12/023,572, filed Jan. 31, 2008, titled PROCESSING SYSTEM FOR FABRICATING COMPOUND NITRIDE SEMICONDUCTOR DEVICES, which is hereby incorporated by reference in its entirety.

A system controller 260 controls activities and operating parameters of the processing system 200. The system controller 260 includes a computer processor, support circuits and a computer-readable memory coupled to the processor. The processor executes system control software, such as a computer program stored in memory. Aspects of the processing system and methods of use are further described in U.S. patent application Ser. No. 11/404,516, filed Apr. 14, 2006, now published as US 2007/024516, titled EPITAXIAL GROWTH OF COMPOUND NITRIDE STRUCTURES, which is hereby incorporated by reference in its entirety.

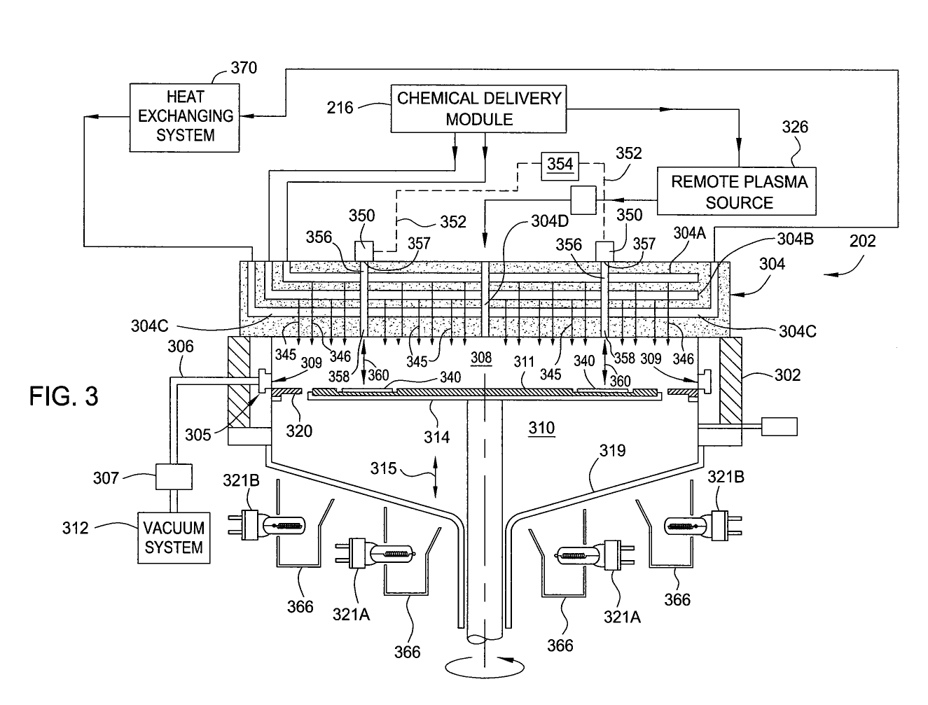

FIG. 3 is a schematic cross-sectional view of an MOCVD chamber 202 according to embodiments described herein. The MOCVD chamber 202 comprises a chamber body 302, a chemical delivery module 216 for delivering precursor gases, carrier gases, cleaning gases, and/or purge gases, a remote plasma system 326 with a plasma source, a susceptor or substrate support 314, and a vacuum system 312. The chamber body 302 encloses a processing volume 308. A showerhead assembly 304 is disposed at one end of the processing volume 308, and a carrier plate 311 is disposed on the substrate support 314 at the other end of the processing volume 308. The substrate support 314 has capability for moving in a vertical direction, as shown by arrow 315. The vertical lift capability may be used to move the substrate support 314 either upward and closer to the showerhead assembly 304 or downward and further away from the showerhead assembly 304. In certain embodiments, the substrate support 314 includes a heating element, for example, a resistive heating element (not shown) for controlling the temperature of the substrate support 314 and consequently controlling the temperature of the carrier plate 311 and substrates 340 positioned on the substrate support 314.

The showerhead assembly 304 has a first processing gas manifold 304A coupled with the chemical delivery module 216 for delivering a first precursor or first process gas mixture to the processing volume 308, a second processing gas manifold 304B coupled with the chemical delivery module 216 for delivering a second precursor or second process gas mixture to the processing volume 308 and one or more temperature control channels 304C coupled with a heat exchanging system 370 for flowing a heat exchanging fluid through the showerhead assembly 304 to help regulate the temperature of the showerhead assembly 304. Suitable heat exchanging fluids include but are not limited to water, water-based ethylene glycol mixtures, a perfluoropolyether (e.g. Galden® fluid), oil-based thermal transfer fluids, or similar fluids. During processing the first precursor or first process gas mixture may be delivered to the processing volume 308 via gas conduits 346 coupled with the first processing gas manifold 304A in the showerhead assembly 304. The gas conduits 346 may pass through, but be isolated from, the second processing gas manifold 304A and the one or more temperature control channels 304C. The second precursor or second process gas mixture may be delivered to the processing volume 308 via gas conduits 345 coupled with the second gas processing manifold 304B. The gas conduits 345 may pass through, but be isolated from, the one or more temperature control channels 304C. Where the remote plasma source is used, the plasma may be delivered to the processing volume 308 via conduit 304D. It should be noted that the process gas mixtures or precursors may comprise one or more precursor gases or process gases as well as carrier gases and dopant gases which may be mixed with the precursor gases.

Exemplary showerheads that may be adapted to practice embodiments described herein are described in U.S. patent application Ser. No. 11/873,132, filed Oct. 16, 2007, now published as US 2009-0098276, entitled MULTI-GAS STRAIGHT CHANNEL SHOWERHEAD, U.S. patent application Ser. No. 11/873,141, filed Oct. 16, 2007, now published as US 2009-0095222, entitled MULTI-GAS SPIRAL CHANNEL SHOWERHEAD, and U.S. patent application Ser. No. 11/873,170, filed Oct. 16, 2007, now published as US 2009-0095221, entitled MULTI-GAS CONCENTRIC INJECTION SHOWERHEAD, all of which are incorporated by reference in their entireties.

A lower dome 319 is disposed at one end of a lower volume 310, and the carrier plate 311 is disposed at the other end of the lower volume 310. The carrier plate 311 is shown in process position, but may be moved to a lower position where, for example, the substrates 340 may be loaded or unloaded. An exhaust ring 320 may be disposed around the periphery of the carrier plate 311 to help prevent deposition from occurring in the lower volume 310 and also help direct exhaust gases from the chamber 202 to exhaust ports 309. The lower dome 319 may be made of transparent material, such as high-purity quartz, to allow light to pass through for radiant heating of the substrates 340. The radiant heating may be provided by a plurality of inner lamps 321A and outer lamps 321B disposed below the lower dome 319 and reflectors 366 may be used to help control the chamber 202 exposure to the radiant energy provided by inner and outer lamps 321A, 321B. Additional rings of lamps may also be used for finer temperature control of the substrates 340.

A purge gas (e.g., a nitrogen containing gas) may be delivered into the chamber 202 from the showerhead assembly 304 and/or from inlet ports or tubes (not shown) disposed below the carrier plate 311 and near the bottom of the chamber body 302. The purge gas enters the lower volume 310 of the chamber 202 and flows upwards past the carrier plate 311 and exhaust ring 320 and into multiple exhaust ports 309 which are disposed around an annular exhaust channel 305. An exhaust conduit 306 connects the annular exhaust channel 305 to a vacuum system 312 which includes a vacuum pump 307. The chamber 202 pressure may be controlled using a valve system which controls the rate at which the exhaust gases are drawn from the annular exhaust channel. Other aspects of the MOCVD chamber 202 are described in U.S. patent application Ser. No. 12/023,520, filed Jan. 31, 2008, and titled CVD APPARATUS, which is herein incorporated by reference in its entirety.

A cleaning gas (e.g., a halogen gas) may be delivered into the chamber 202 from the showerhead assembly 304 and/or from inlet ports or tubes (not shown) disposed near the processing volume 308. The cleaning gas enters the processing volume 308 of the chamber 202 to remove deposits from chamber components such as the substrate support 314 and the showerhead assembly 304 and exits the chamber via multiple exhaust ports 309 which are disposed around the annular exhaust channel 305.

The chemical delivery module 216 supplies chemicals to the MOCVD chamber 202. Reactive gases, carrier gases, purge gases, and cleaning gases are supplied from the chemical delivery system through supply lines and into the chamber 202. In one embodiment, the gases are supplied through supply lines and into a gas mixing box where they are mixed together and delivered to showerhead 304. In another embodiment, the gases are delivered to the showerhead 304 through separate supply lines and mixed within the chamber 202. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and cleaning gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

Remote plasma system 326 can produce plasma for selected applications, such as chamber cleaning or etching residue from a process substrate. The remote plasma system 326 may be a remote microwave plasma system. Plasma species produced in the remote plasma system 326 from precursors supplied via an input line are sent via a conduit for dispersion through the showerhead assembly 304 to the MOCVD chamber 202. Precursor gases for a cleaning application may include chlorine containing gases, fluorine containing gases, iodine containing gases, bromine containing gases, nitrogen containing gases, and/or other reactive elements. Remote plasma system 326 may also be adapted to deposit CVD layers flowing appropriate deposition precursor gases into remote plasma system 326 during a layer deposition process. The remote plasma system 326 may used to deliver active nitrogen species to the processing volume 308.

The temperature of the walls of the MOCVD chamber 202 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during an in-situ plasma process, or to limit formation of deposition products on the walls of the chamber. Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

In order to check the quality of the deposited layers, it is often desirable to monitor the processes either during processing or after processing so that any low-quality layers that deviate from processing parameter set points can be removed and replaced (either completely or partially) before the substrate completes processing. In FIG. 3, the MOCVD chamber 202 is shown to include at least one sensor or metrology tool 350 according to one embodiment of the invention. One or more metrology tools 350 may be coupled to the showerhead assembly 304 in order to measure substrate processing parameters, such as temperature and pressure, for example, and various properties of films deposited on the substrates, such as thickness, real-time film growth rate, alloy composition, stress, roughness, photoluminescence, electroluminescence, mobility, carrier concentration, or other film properties. It is contemplated that metrology tools 350 may be disposed along sidewalls of the chamber body 302 or in other positions on the chamber body 302. Data from the metrology tools 350 may be sent along signal lines 352 to a system controller 354 so that the data can be monitored. The system controller 354 may be configured similar to the system controller 260. The system controller 354 may be adapted to automatically provide control signals to the system 200 or the MOCVD chamber 202 in response to the metrology data to provide a closed loop control of the respective system.

Each of the metrology tools 350 may be coupled to a conduit 356, which includes a tube, extended housing or channel, which forms a vacuum seal with the showerhead assembly 304 or chamber body 302, and which allows each metrology tool 350 to access the processing volume 308 of the chamber 202, while still maintaining vacuum. One end of each conduit 356 may be located near ports 358 disposed within the showerhead assembly 304 or chamber body 302. The ports 358 are in fluid communication with the interior volume of chamber 202. In another embodiment, one or more ports 358 include a window 357, which allows light to pass through, but which forms a vacuum seal to prevent fluid communication with the interior of the chamber 202.

Each conduit 356 may house a sensor/transducer probe or other device, and/or provides a path for a directed radiation beam, such as a laser beam. Each port 358 may be adapted to flow a purge gas, which may be an inert gas, therethrough to prevent condensation on devices within the ports 358 and conduits 356 to enable accurate in-situ measurements. In one example, the metrology tool 350 is a reflectometer, which is used to measure film thickness and quality. The reflectometer may be located on the showerhead assembly 304 so that a beam 360, which may be a radiation beam or particle (e.g., laser beam, ion beam), may be reflected from the surface of a substrate 340. As shown in FIG. 3, the beam 360 may be directed substantially perpendicular to the substrate surface.

In general, the metrology tools 350 may include reflectance and wafer curvature measurement devices that are particularly suitable as in-situ tools. Measuring reflectance can be used to determine thickness, growth rates and morphology with roughness and waviness parameters. Measuring curvature can be used to determine wafer curvature or bowing and stress parameters. All of these measurements can be performed during the layer(s) growth in the same chamber without growth interruption. Other metrology tools may also be used, such as photoluminescence (PL), electroluminescence (EL), X-ray diffraction (XRD), atomic force microscope (AFM), mobility and capacitance-voltage (C-V) measurement.

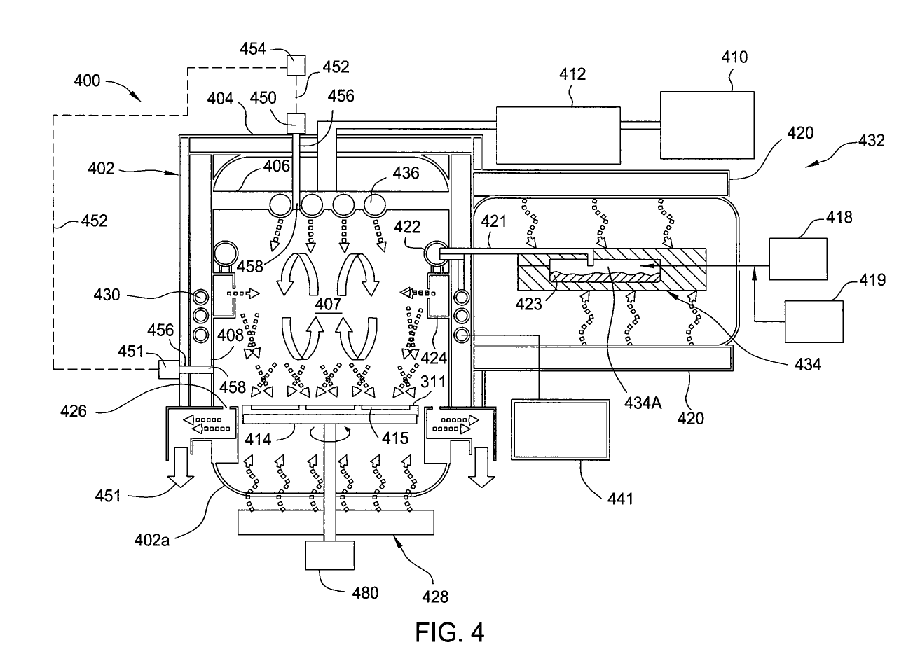

FIG. 4 is a schematic cross-sectional view of a hydride vapor phase epitaxy (HVPE) chamber 400 for fabricating compound nitride semiconductor devices according to embodiments of the invention. The HVPE chamber 400 may be one or more of the chambers 202a, 202b or 202c, as described above with reference to system 200. The HVPE chamber 400 includes a chamber body 402 enclosed by a lid 404. The chamber body 402 and the lid 404 define a processing volume 407. A showerhead 406 is disposed in an upper region of the processing volume 407. A susceptor 414 is disposed opposing the showerhead 406 in the processing volume 407. The susceptor 414 is configured to support a plurality of substrates 415 thereon during processing. The plurality of substrates 415 is disposed on a carrier plate 311 which is supported by the susceptor 414. The susceptor 414 may be rotated by a motor 480, and may be formed from a variety of materials, including SiC or SiC-coated graphite. In one example, the susceptor 414 may be rotated at about 2 RPM to about 100 RPM, such as at about 30 RPM. Rotating the susceptor 414 aids in providing uniform exposure of the processing gases to each substrate.

The HVPE chamber 400 includes a heating assembly 428 configured to heat the substrates 415 on the susceptor 414. The chamber bottom 402a may be formed from quartz, and the heating assembly 428 may be a lamp assembly disposed under the chamber bottom 402a to heat the substrates 415 through the quartz chamber bottom 402a. In one example, the heating assembly 428 includes an array of lamps that are distributed to provide a uniform temperature distribution across the substrates, substrate carrier, and/or susceptor.

The HVPE chamber 400 further includes precursor supplying pipes 422, 424 disposed inside the side wall 408 of the chamber 402. The pipes 422 and 424 are in fluid communication with the processing volume 407 and an inlet tube 421 found in a precursor source module 432. The showerhead 406 is in fluid communication with the processing volume 407 and a gas source 410. The processing volume 407 is in fluid communication with an exhaust 451 via an annular port 426.

The HVPE chamber 400 further includes a heater 430 embedded within the walls 408 of the chamber body 402. The heater elements 430 embedded in the walls 408 may provide additional heat if needed during the deposition process. A thermocouple, positioned in the showerhead for instance, may be used to measure the temperature inside the processing chamber. Output from the thermocouple may be fed back to a controller 441 that controls the temperature of the walls of the chamber body 402 by adjusting the power delivered to the heater elements 430 (e.g., resistive heating elements) based upon the reading from a thermocouple (not shown). For example, if the chamber is too cool, the heater 430 is turned on. If the chamber is too hot, the heater 430 is turned off. Additionally, the amount of heat provided from the heater 430 may be controlled so that the amount of heat provided from the heater 430 is minimized.

Processing gas from the gas source 410 is delivered to the processing volume 407 through a gas plenum 436 disposed in the gas distribution showerhead 406. The gas source 410 may comprise a nitrogen containing compound. In one example, the gas source 410 is configured to deliver a gas that includes ammonia or nitrogen. An inert gas such as helium or diatomic nitrogen may be introduced as well, either through the gas distribution showerhead 406 or through the pipe 424, disposed on the walls 408 of the chamber 402. An energy source 412 may be disposed between the gas source 410 and the gas distribution showerhead 406. The energy source 412 may include a heater or a remote RF plasma source. The energy source 412 may provide energy to the gas delivered from the gas source 410, so that radicals or ions can be formed, so that the nitrogen in the nitrogen containing gas is more reactive.

The source module 432 comprises a halogen gas source 418 connected to a well 434A of a source boat 434 and an inert gas source 419 connected to the well 434A. A source material 423, such as aluminum, gallium or indium is disposed in the well 434A. A heating source 420 surrounds the source boat 434. An inlet tube 421 connects the well 434A to the processing volume 407 via the pipes 422, 424.

During processing a halogen gas (e.g., Cl₂, Br₂, or I₂) may be delivered from the halogen gas source 418 to the well 434A of the source boat 434 to create a metal halide precursor (e.g., GaCl, GaCl₃, AlCl₃). The interaction of the halogen gas and the solid or liquid source material 423 allows a metal halide precursor to be formed. The source boat 434 may be heated by the heating source 420 to heat the source material 423 and allow the metal halide precursor to be formed. The metal halide precursor is then delivered to the processing volume 407 of the HVPE chamber 400 through an inlet tube 421. An inert gas (e.g., Ar, N₂) delivered from the inert gas source 419 may carry, or push, the metal halide precursor formed in the well 434A through the inlet tube 421 and pipes 422 and 424 to the processing volume 407 of the HVPE chamber 400. A nitrogen-containing precursor gas (e.g., ammonia (NH₃), N₂) may be introduced into the processing volume 407 through the showerhead 406, while the metal halide precursor is also provided to the processing volume 407, so that a metal nitride layer can be formed on the surface of the substrates 415 disposed in the processing volume 407.

In FIG. 4, the HVPE chamber 400 is shown to include at least one sensor or metrology tool 450 according to one embodiment of the invention. One or more sensors and/or metrology tools 450 may be coupled to the lid 404 and the showerhead 406 in order to measure substrate processing parameters, such as temperature and pressure, for example, and various properties of films which are deposited on the substrates, such as thickness, real-time film growth rate, alloy composition, stress, roughness, photoluminescence, electroluminescence, mobility, carrier concentration, or other film properties. Additional sensors such as 451 may be disposed along sidewalls of the chamber body 402. It is contemplated that the sensors may be located in other positions on chamber body 402. Data from the sensors and/or metrology tools 450, 451 can be sent along signal lines 452 to a system controller 454 so that the system controller 454 can monitor the data. The system controller 454 may be configured similar to the system controller 260. In one embodiment, the system controller 454 is adapted to automatically provide control signals to system 200 or HVPE chamber 400 in response to the metrology/sensor data to provide a closed loop control system.

Each of the sensors and/or metrology tools 450, 451 is coupled to a conduit 456 which comprises a tube, extended housing or channel which forms a vacuum seal with the lid 404 or chamber body 402 and which allows each sensor and/or metrology tool 450, 451 to access the interior volume (e.g., processing volume 407) of chamber 400 while still maintaining chamber vacuum. One end of each conduit 456 is located near ports 458 disposed within showerhead 406 and/or chamber body 402. The ports 458 are in fluid communication with the interior volume of chamber 400. In another embodiment, one or more ports 458 include a window 457 which allows light to pass through but which forms a vacuum seal to prevent fluid communication with the interior of chamber 400.

Each conduit 456 houses a sensor/transducer probe or other device, and/or provides a path for a directed radiation beam, such as a laser beam. Each port 458 is adapted to flow a purge gas (which may be an inert gas) to prevent condensation on devices within ports 458 and conduits 456 and enable accurate in-situ measurements. The purge gas may have annular flow around the sensor probe or other device which is disposed inside conduit 456 and near port 458.

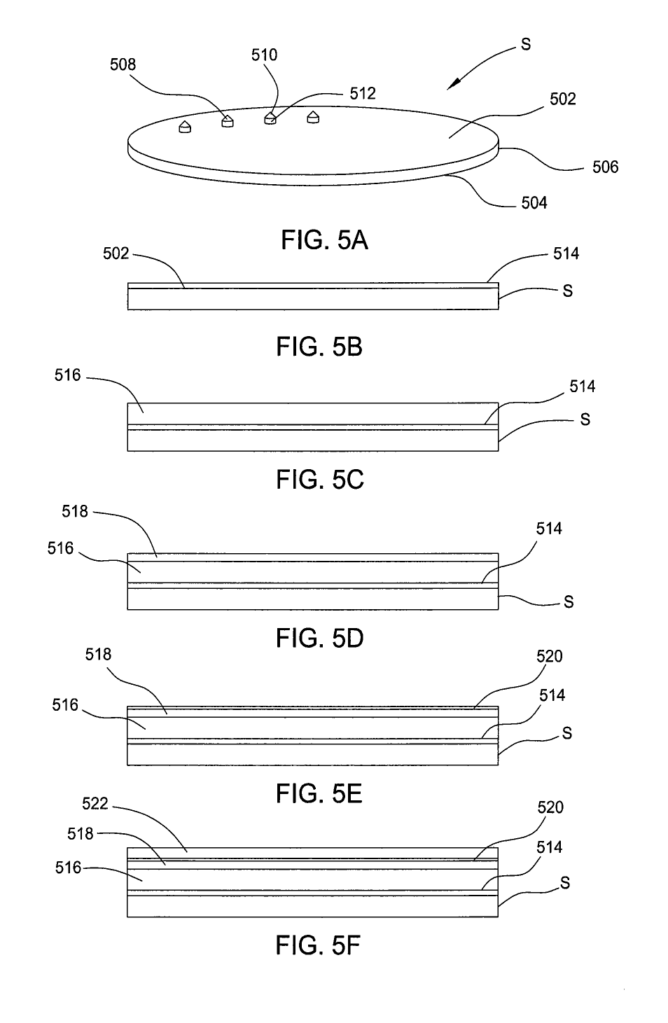

FIGS. 5A-5F illustrate a process of forming, repairing and/or salvaging components during the formation of compound nitride semiconductor devices according to embodiments of the invention. In FIG. 5A, a patterned substrate S is illustrated. The patterned substrate S includes a top surface 502, a bottom surface 504 and a peripheral edge or bevel 506. On the top surface 502 of the substrate S, a plurality of features 508 are formed. In one embodiment, the features 508 include a top conical surface 510, and a bottom cylindrical surface 512 that connects the top conical surface 510 to the top surface 502 of the substrate S. The features 508 enhance the light extraction efficiency for the final LED's, and may increase the crystal quality of the deposited layers to the top surface 502 of the substrate S. The substrate S and the features 508 may be integral with one another and may be formed of sapphire, silicon, SiO₂, ZnO, MgO, LiAlO₂ or silicon carbide (SiC). The size of the substrate S may range in diameter from about 101.6 mm (4″) to about 152.4 mm (6″) or even about 203.2 mm (8″) or greater. While in the embodiment shown in FIG. 5A, the substrate S is circular in shape, other shapes may be used such as rectangular, square, hexagonal, etc. The features 508 may be about 3 mm in diameter and about 3 mm high. The substrate may be provided with different crystalline orientations to promote non-polar or semi-polar growth of GaN.

The above-described substrates, are useful in the formation of compound nitride semiconductor devices. These substrates can be relatively expensive depending on the selected material, the cost of forming features thereon and the size of the substrate. In some cases, the formation process may inadvertently produce low quality or even defective layers, which subsequently produce defective devices. Embodiments of the present invention provide systems and methods that are useful in recovering substrates and/or high quality layers from these low quality or defective devices, by removing the defective layers as is described below.

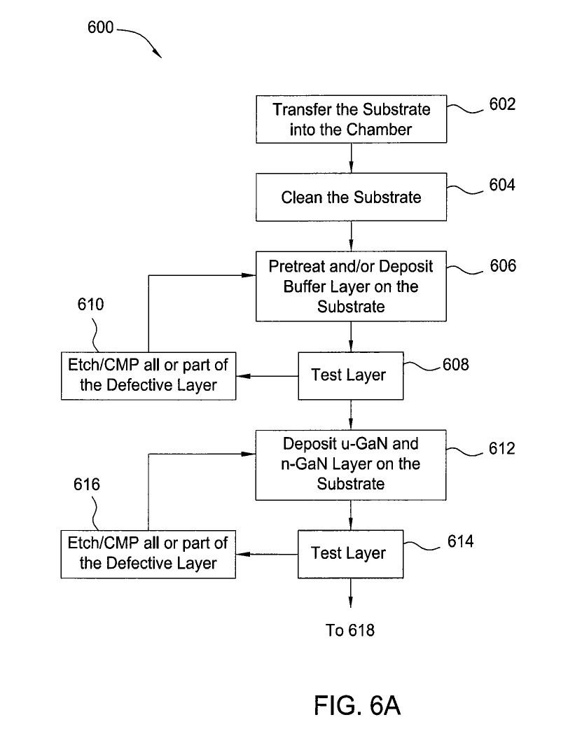

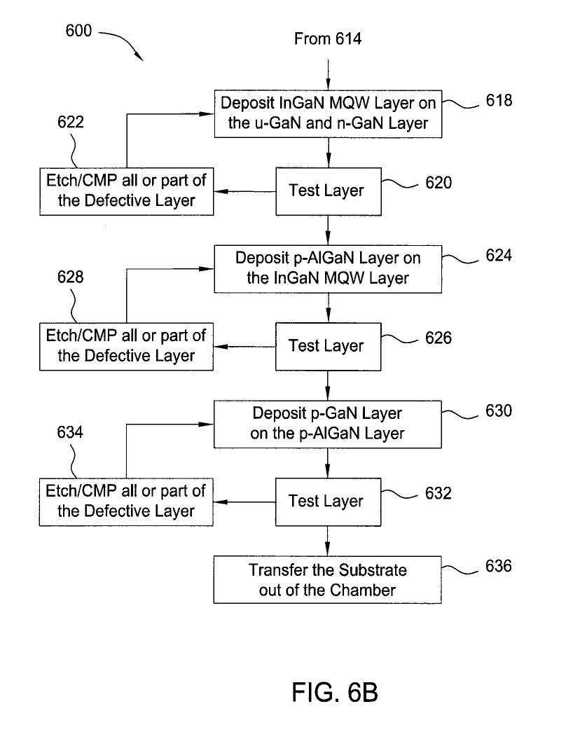

In FIGS. 6A-6B, a flow diagram of one embodiment of a process 600 that may be used for forming and/or repairing compound nitride semiconductor devices is shown. At block 602 one or more substrates (such as substrate S in FIG. 5A) are transferred into a substrate processing chamber (such as chamber 202 in FIG. 3). Although process 600 is primarily described with respect to a substrate S, it should be noted that the process 600 applies equally to a the plurality of substrates positioned on the carrier plate 250 as described with respect to FIG. 2. For instance, if a problem is detected in one substrate positioned on the carrier plate 250 along with a plurality of other substrates, it may be assumed that a process flaw occurred, and all substrates may be subjected to the corrective action described herein.

At block 604, the substrate is cleaned. In one embodiment, the substrate is scanned to determine whether the substrate has an unacceptable number of contaminant particles. If the substrate S does not have an unacceptable number of particles, the substrate S is not cleaned. If the number of contaminant particles exceeds a predetermined number, the substrate S is cleaned prior to any deposition processes. The one or more substrates may be cleaned by flowing chlorine gas at a flow rate between about 200 sccm and about 1000 sccm and ammonia at a flow rate between about 500 sccm and about 9000 sccm within a susceptor temperature range between about 625° C. and about 1000° C. Alternatively, the cleaning gas may include ammonia and a carrier gas. In some embodiments, the substrates may not need to be cleaned or may have been previously cleaned prior to being transferred into the chamber, and block 604 may be omitted.

At block 606, a pretreatment process and/or buffer layer is grown over the substrate in a first processing chamber, such as the MOCVD chamber 202 using MOCVD precursor gases, for example, TMG, NH₃, and N₂ at a susceptor temperature of about 550° C. and a chamber pressure of between about 100 Torr and about 600 Torr, such as about 300 Torr. In FIG. 5B, a buffer layer 514 is deposited on the top surface 502 of substrate S. The buffer layer 514 may be formed of GaN or AlN and may be deposited to a thickness of between about 200 Å and about 500 Å.

At block 608, after deposition of the buffer layer 514, the buffer layer 514 may be subjected to a test of its quality. The test may be conducted in situ, the first processing chamber, i.e., either in the chamber 202 or the chamber 400 using sensors and/or metrology tools 350, 450 and/or 451. Alternatively, the carrier plate 250 and the substrates S are transferred out of either the MOCVD chamber 202 or the HVPE chamber 400 and into a test chamber (not shown) that may be positioned in the processing system 200, for instance. The layer 514 is then tested either optically or electrically to determine if the layer is within process parameters. The buffer layer 514 can be monitored in situ during its growth by reflectance to obtain the thickness, growth rates and roughness. The test can also be done after the growth with a process interruption in the same chamber or another chamber. If the layer 514 is within the required parameters, the process proceeds to block 612. If the layer 514, is not within the required parameters, the process proceeds to block 610. An example of a required parameter of the buffer layer 514 is a surface roughness of between about 1 RMS Å and about 200 RMS Å.

In block 610, the defective layers are removed using a halogen gas-based etching process, a chemical mechanical polishing (CMP) process, a combination thereof or other suitable layer removal technique. The removal of the defective layers may be performed in situ in the first processing chamber that was used to deposit the buffer layer 514, such as chamber 202 using remote plasma source 326 and an etching gas such as chlorine (Cl₂) to selectively etch the buffer layer 514 without damaging the underlying substrate S. Alternatively, the carrier plate 250 and substrates S may be transferred to a separate etching chamber, such as etching chamber 280 and/or a CMP station (not shown) for removal of the defective layers. In some processes, only a part of the buffer layer 514 may need to be removed, leaving the residual buffer layer on top of the substrate S as shown in FIG. 5B. In other processes, the entire buffer layer 514 may be removed leaving only the substrate S as shown in FIG. 5A. In a process in which the entire buffer layer 514 is removed, CMP is not used to prevent removal of the features 508.

Once the defective layer(s) is removed in block 610, the process 600 returns to block 604, if all of the buffer layer 514 has been removed, to clean the substrate of any residual material (if necessary) prior to re-depositing the buffer layer 514 at block 606. If only some of the buffer layer 514 is removed, the process returns to block 606, as shown in FIG. 6A, to redeposit buffer layer material to rebuild the thickness of the buffer layer 514 to compensate for the removed portion of the buffer layer 514 in the first processing chamber.

Once a deposited buffer layer 514 having the required parameters is formed on the substrate S, the process proceeds to block 612. In one embodiment, the substrate is scanned to determine whether the substrate has an unacceptable number of contaminant particles. If the substrate S does not have an unacceptable number of particles, the substrate S is not cleaned. If the number of contaminant particles exceeds a predetermined number, the substrate S is cleaned prior to any further deposition processes. In block 612, a relatively thick u-GaN/n-GaN layer is deposited, which in this example is performed in a processing chamber, which may be the first processing chamber, such as the chamber 202 using MOCVD precursor gases (e.g., TMG, NH₃, and N₂) at a susceptor temperature of about 1050° C. and a chamber pressure of between about 100 Torr and about 600 Torr, such as about 300 Torr. FIG. 5C shows the u-GaN/n-GaN layer 516 deposited on top of the buffer layer 514. The u-GaN/n-GaN layer 516 may be deposited to a thickness of between about 2.0 μm and about 20 μm, such as about 4.0 μm.

In another embodiment, an HVPE process is used to deposit layers 514 and 516 and the first processing chamber is an HVPE chamber such as chamber 400, and the carrier plate 250 containing one or more substrates S is transferred into the HVPE chamber 400. The HVPE chamber 400 is configured to provide rapid deposition of GaN. At block 606, a pretreatment process and/or buffer layer is grown over the substrate in the HVPE chamber 400 using HVPE precursor gases, for example, GaCl₃ and NH₃ at a susceptor temperature of about 550° C. and at a chamber pressure of between about 100 Torr and about 600 Torr, such as about 450 Torr. This is followed by growth of a relatively thick u-GaN/n-GaN layer, which in this example is performed using HVPE precursor gases, for example, GaCl₃ and NH₃ at a susceptor temperature of about 1050° C. and a chamber pressure of about 450 Torr at block 612.

In one embodiment, the GaN film is formed over the substrate by an HVPE process at a susceptor temperature between about 700° C. and about 1100° C. by flowing a gallium containing precursor and ammonia. The gallium containing precursor is generated by flowing chlorine gas at a flow rate between about 20 sccm and about 150 sccm over liquid gallium maintained at a temperature between about 700° C. and about 950° C., such as about 800° C. Ammonia is supplied to the processing chamber at a flow rate within a range between about 6 SLM and about 20 SLM. The GaN has a growth rate between about 0.3 microns/hour and about 25 microns/hour, with growth rates up to about 100 microns/hour achievable.

At block 614, after deposition of the u-GaN and n-GaN layer 516, the deposited u-GaN and n-GaN layer 516 may be subjected to a test of its quality. The test may be conducted in situ either in the first processing chamber, such as the chamber 202 or the chamber 400, using sensors and/or metrology tools 350, 450 and/or 451. Alternatively, the carrier plate 250 and the substrates S are transferred out of either the MOCVD chamber 202 or the HVPE chamber 400 and into a test chamber (not shown) that is part of or outside of the system 200. The layer 516 is then tested either optically or electrically to determine if the layer is within process parameters. The n-GaN layer can be monitored in situ during the growth by reflectance to obtain the thickness, growth rates and roughness. In addition, in situ curvature measurement can be used to determine wafer curvature/bowing and stress. The test can also be done after the growth with a process interruption in the same chamber or another chamber to get the crystal quality, mobility, or carrier concentration. If the layer 516 is within the required parameters, the process proceeds to block 618 (see FIG. 6B). If the layer 516 is not within the required parameters, the process proceeds to block 616. Examples of the required parameters of the deposited u-Gan layers may include a growth rate of between about 0.1 and about 20 μm/hr, uniformity of between about 0.1 and about 5 percent, X-ray diffraction (XRD) (002) rocking curve full width at half maximum (FWHM) less than about 300 arcsec, and XRD (102) FWHM less than about 350 arcsec. Examples of the required parameters of the deposited n-Gan layers may include growth rate between about 0.1 and about 20 μm/hr, uniformity between about 0.1 and 5%, XRD (002) FWHM less than about 300 arcsec, XRD (102) FWHM less than about 350 arcsec, carrier concentration between about 1×10¹⁷ and about 5×10¹⁹ electron/cm³, and mobility between about 50 and about 1000 cm²/V*s.

In block 616, the defective layers are removed using a halogen gas-based etching process, a chemical mechanical polishing (CMP) process, a combination thereof or other suitable layer removal technique. The removal of the defective layers may be performed in situ in the first processing chamber, which is the same chamber used to deposit the u-GaN and n-GaN layer 516, such as chamber 202 using remote plasma source 326 and an etching gas such as chlorine (Cl₂). Alternatively, the carrier plate 250 and substrates S may be transferred to a separate etching chamber, such as etching chamber 280, and/or a CMP station (not shown) for removal of the defective layers. In some processes, only a part of the u-GaN and n-GaN layer 516 may need to be removed, leaving the residual GaN layer on top of the buffer layer 514 as shown in FIG. 5C. In other processes, the entire u-GaN and n-GaN layer 516 may be removed leaving only the buffer layer 514 on substrate S as shown in FIG. 5B. In yet other processes, it may be necessary to remove both the u-GaN and n-GaN layer 516 and the buffer layer 514, leaving only the substrate S as shown in FIG. 5A. In a process in which the entire buffer layer 514 is removed, CMP is not used to prevent removal of the features 508.

Once the defective layer(s) is removed in block 616, the process 600 returns to block 604 if all of the layers have been removed to clean the substrate of any residual material. If only some or all of the u-GaN and n-GaN layer 516 is removed, (leaving the buffer layer 514 intact) the process returns to block 612, as shown in FIG. 6A, to redeposit the removed portion of the u-GaN and n-GaN layer 516.

Once a deposited layer 516 having the required parameters is formed on the substrate S, the process proceeds to block 618. In one embodiment, the substrate is scanned to determine whether the substrate has an unacceptable number of contaminant particles. If the substrate S does not have an unacceptable number of particles, the substrate S is not cleaned. If the number of contaminant particles exceeds a predetermined number, the substrate S is cleaned prior to any deposition processes. An InGaN multi-quantum-well (MQW) active layer 518 is then grown on top of the u-GaN and n-GaN layer 516 using MOCVD precursor gases, for example, TMG, TMI, and NH₃ in a H₂ carrier gas flow at a susceptor temperature of between about 750° C. and about 800° C. and a second processing chamber at a pressure between about 100 Torr and about 300 Torr, such as about 300 Torr, as shown in FIG. 5D.

At block 620, after deposition of the InGaN MQW active layer 518, the InGaN MQW active layer 518 may be subjected to a test of its quality. The test may be conducted in situ in the second processing chamber, such as the chamber 202 or the chamber 400 (using a metrology window or test probe, for example, (not shown)) or the carrier plate 250 and the substrates S may be transferred out of either the MOCVD chamber 202 or the HVPE chamber 400 and into a test chamber (not shown). The layer 518 is then tested either optically or electrically to determine if the layer is within process parameters. The InGaN MQW layer can be monitored in situ during the growth by reflectance to obtain the period thickness, growth rates and roughness. In addition, in situ curvature measurement can get wafer curvature/bowing and stress. The test can also be done after the growth with a process interruption in the same chamber or another chamber to get the wavelength of the photoluminescence emission, PL intensity, period thickness, etc. If the layer 518 is within the required parameters, the process proceeds to block 624. If the layer 518 is not within the required parameters, the process proceeds to block 622. Examples of required parameters of the InGaN MQW layer 518 may include PL wavelength between about 260 and about 550 nm, PL FWHM between about 15 and about 30 nm, PL uniformity standard deviation between about 0.5 and about 5 nm, PL (maximum-minimum) between about 3.0 and about 15.0, and MQW period thickness variation between about 1.0 and about 5.0%.

In block 622, the defective layer(s) is removed using a halogen gas-based etching process, a chemical mechanical polishing (CMP) process, a combination thereof or other suitable layer removal technique. The removal of the defective layers may be performed in situ in the second processing chamber, which is the same chamber used to deposit the layers, such as chamber 202 using remote plasma source 326 and an etching gas such as chlorine (Cl₂). Alternatively, the carrier plate 250 and substrates S may be transferred to a separate etching chamber, such as the etching chamber 280, and/or a CMP station (not shown) for removal of the defective layers. In some processes, only a part of the InGaN MQW active layer 518 may be removed, leaving the residual InGaN MQW active layer on top of the layer 516 as shown in FIG. 5D. In other processes, the entire InGaN MQW layer 518 may be removed leaving only the layers 514 and 516 on substrate S, as shown in FIG. 5C. In yet other processes, it may be necessary to remove all of the layers, leaving only the substrate S as shown in FIG. 5A. In a process in which the entire buffer layer 514 is removed, CMP is not used to prevent removal of the features 508.

Once the defective layers are removed in block 622, the process 600 returns to block 604 if all of the layers have been removed to clean the substrate of any residual material. If only some or all of the u-GaN and n-GaN layer 516 is removed, (leaving the buffer layer 514 intact) the process returns to block 612 to redeposit the removed portion of the u-GaN and n-GaN layer 516. If only some or all of the InGaN MQW active layer 518 is removed, (leaving the u-GaN and n-GaN layer 516 intact) the process returns to block 618, as shown in FIG. 6B, to redeposit the removed portion of the InGaN MQW active layer 518.

After deposition of an InGaN MQW layer 518 that is within parameters, at block 624, a p-AlGaN layer 520 is grown on the InGaN MQW layer 518, as shown in FIG. 5E. In one embodiment, the substrate is first scanned to determine whether the substrate has an unacceptable number of contaminant particles. If the substrate S does not have an unacceptable number of particles, the substrate S is not cleaned. If the number of contaminant particles exceeds a predetermined number, the substrate S is cleaned prior to any deposition processes. The p-AlGaN layer 520 is grown using MOCVD precursors, such as, TMA, TMG, and NH₃ provided in a H₂ carrier gas flow at a susceptor temperature of about 1020° C. and a pressure of about 200 Torr in a third processing chamber.

At block 626, after deposition of the p-AlGaN layer 520, the p-AlGaN layer 520 may be subjected to a test of its quality. The test may be conducted in situ either in the third processing chamber, such as chamber 202 or the chamber 400. The layer 520 is then tested either optically or electrically to determine if the layer is within process parameters. The p-AlGaN layer can be monitored in situ during the growth by reflectance to obtain the thickness, growth rates, alloy composition and roughness. The test can also be done after the growth with a process interruption in the same chamber or another chamber to get the alloy composition, mobility, or carrier concentration. If the layer 520 is within the required parameters, the process proceeds to block 630. If the layer 520 is not within the required parameters, the process proceeds to block 628. Examples of required parameters include Al composition between about 5.0 and about 50% and Al composition uniformity (maximum-minimum) between about 0.1 and about 5%.

In block 628, the defective layer(s) is removed using a halogen gas-based etching process, a chemical mechanical polishing (CMP) process, or a combination thereof or other suitable layer removal technique. The removal of the defective layers may be performed in situ in the third processing chamber, which is the same chamber used to deposit the layers, such as chamber 202 using remote plasma source 326 and an etching gas such as chlorine (Cl₂). Alternatively, the carrier plate 250 and substrates S may be transferred to a separate etching chamber, such as the etching chamber 280, and/or a CMP station (not shown) that is part of or outside the system 200 for removal of the defective layers. In some processes, only a part of the p-AlGaN layer 520 may need to be removed, leaving the residual p-AlGaN layer 520 as shown in FIG. 5E. In other processes, the entire p-AlGaN layer 520 may need to be removed leaving only the layers 514, 516 and 518 on substrate S as shown in FIG. 5D. In yet other processes, it may be necessary to some or all of the other layers, as described above.

Once the defective portion of layer 520 is removed in block 628, the process 600 returns to block 624 (as shown in FIG. 6B), if only some or all of the layer 520 is removed, (leaving the other layers intact) to redeposit the removed portion of the p-AlGaN layer 520. If other layers are removed, the process returns to the appropriate block to redeposit the removed portion of the layers.

Once a deposited layer 520 having the required parameters is formed on the substrate S, the process proceeds to block 630. At block 630, a p-GaN layer 522 is grown on the p-AlGaN layer 520 using flows of TMG, NH₃, Cp₂Mg, and N₂ at a susceptor temperature of about 1020° C. and a pressure of about 100 Torr, as shown in FIG. 5F in the third processing chamber. The p-GaN layer 522 may be grown in an ammonia free environment using flows of TMG, Cp₂Mg, and N₂ at a susceptor temperature of between about 850° C. and about 1050° C. During formation of the p-GaN layer 522, the one or more substrates are heated at a temperature ramp-up rate between about 5° C./second to about 10° C./second.

At block 632, after deposition of the p-GaN layer 522, the p-GaN layer 522 may be subjected to a test of its quality. The test may be conducted in situ in the third processing chamber, such as in chamber 202 or in chamber 400 (using a metrology window or test probe, for example, (not shown)), or the carrier plate 250 and the substrates S are transferred out of either the MOCVD chamber 202 or the HVPE chamber 400 and into a test chamber (not shown) that is part of or outside the system 200. The layer 522 is then tested either optically or electrically to determine if the layer is within process parameters. The p-GaN layer can be monitored in situ during the growth by reflectance to obtain the thickness, growth rates, and roughness. The test can also be done after the growth with a process interruption in the same chamber or another chamber to get the electroluminescence, light output power, L-I-V, reverse current and voltage, mobility, and carrier concentration. If the layer 522 is within the required parameters, the process proceeds to block 636. If the layer 522 is not within the required parameters, the process proceeds to block 634. Examples of required parameters of the p-Gan layer 522 may include carrier concentration between about 1×10¹⁷ and about 1×10¹⁸ holes/cm³ and mobility between about 1.0 and about 50 cm²/V*s.

In block 634, the defective layer(s) is removed using a halogen gas-based etching process, a chemical mechanical polishing (CMP) process, a combination thereof or other suitable layer removal technique. The removal of the defective layers may be performed in situ in the third processing chamber, which is the same chamber used to deposit the layers, such as chamber 202 using remote plasma source 326 and an etching gas such as chlorine (Cl₂). Alternatively, the carrier plate 250 and substrates S may be transferred to a separate etching chamber (not shown) and/or a CMP station (not shown) that is part of or outside the system 200 for removal of the defective layers. In some processes, only a part of the p-GaN layer 522 may need to be removed, leaving the residual p-GaN layer 522 as shown in FIG. 5F. In other processes, the entire p-GaN layer 522 may need to be removed leaving only the layers 514, 516, 518 and 520 on substrate S as shown in FIG. 5E. In yet other processes, it may be necessary to remove some or all of the other layers, as described above.

Once the defective portion of layer 522 is removed in block 634, the process 600 returns to block 630 (as shown in FIG. 6B), if only some or all of the layer 522 is removed, (leaving the other layers intact) to redeposit the removed portion of the p-GaN layer 522 in the third processing chamber. If other layers are removed, the process returns to the appropriate block to redeposit the removed portion of the layers.

After the p-AlGaN and p-GaN layers are grown, at block 636 of process 600, the completed structure is then transferred out of the third processing chamber, such as chamber 202 or 400. The completed structure may either be transferred to the batch loadlock chamber 209 for storage or may exit the processing system 200 via the loadlock chamber 208 and the load station 210.

In one embodiment, multiple carrier plates 250 may be individually transferred into and out of each substrate processing chamber for deposition processes, each carrier plate 250 may then be stored in the batch loadlock chamber 209 and/or the loadlock chamber 208 while either the subsequent processing chamber is being cleaned or the subsequent processing chamber is currently occupied.

While the above process 600 is described as testing each layer 514-522 after it is deposited, some of the testing processes in blocks 608, 614, 620, 626 or 632 may be omitted, particularly when the deposition of those layers are typically successful. Further, the first deposition process may be performed and the device may only be tested after all of the layers have been deposited. By reducing the number or by being selective as to when the tests are performed, the overall throughput of the substrates may be increased.

While the foregoing is directed to embodiments of the present invention, other and further embodiments of the invention may be devised without departing from the basic scope thereof, and the scope thereof is determined by the claims that follow.

1. A method for fabricating a compound nitride semiconductor structure within desired parameters, comprising:
depositing a first group-III nitride layer over one or more substrates within a first processing chamber;
testing the first group-III nitride layer to determine whether the first group-III nitride layer is within the desired parameters;
removing at least a portion of the first group-III nitride layer if the first layer is not within the desired parameters; and
depositing an additional first group-III nitride layer to replace the removed portion of the first group-III nitride layer.

2. The method of claim 1, wherein depositing the first group-III nitride layer and testing the first group-III nitride layer are both performed in the first processing chamber.

3. The method of claim 2, wherein removing at least a portion of the first group-III nitride layer and depositing the additional first group-III nitride layer are both performed in the first processing chamber.

4. The method of claim 1, further comprising depositing a second group-III nitride layer over the one or more substrates.

5. The method of claim 4, further comprising:
testing the second group-III nitride layer to determine whether the second group-III nitride layer is within the desired parameters;
removing at least a portion of the second group-III nitride layer if the second group-III nitride layer is not within the desired parameters; and
depositing an additional second group-III nitride layer to replace the removed portion of the second group-III nitride layer.

6. The method of claim 5, further comprising depositing a third group-III nitride layer over the one or more substrates.

7. The method of claim 6, further comprising:
testing the third group-III nitride layer to determine whether the third group-III nitride layer is within the desired parameters;
removing at least a portion of the third group-III nitride layer if the third group-III nitride layer is not within the desired parameters; and
depositing an additional third group-III nitride layer to replace the removed portion of the third group-III nitride layer.

8. The method of claim 7, further comprising depositing a fourth group-III nitride layer over the one or more substrates.

9. The method of claim 8, wherein the first group-III nitride layer and the fourth group-III nitride layer comprise the same group-III element.

10. The method of claim 8, further comprising:
testing the fourth group-III nitride layer to determine if the fourth group-III nitride layer is within the desired parameters;
removing at least a portion of the fourth group-III nitride layer if the fourth group-III nitride layer is not within the desired parameters; and
depositing an additional fourth group-III nitride layer to replace the removed portion of the fourth group-III nitride layer.

11. The method of claim 10, wherein:
the first and fourth group-III nitride layers comprise GaN;
the second group-III nitride layer comprises InGaN; and
the third group-III nitride layer comprises AlGaN.

12. The method of claim 11, wherein the third group-III nitride layer further comprises a p-type dopant.

13. The method of claim 12, wherein the p-type dopant comprises Bis(cyclopentadienyl) magnesium (Cp₂Mg).

14. The method of claim 1, further comprising depositing a buffer layer over the one or more substrates prior to depositing the first group-III nitride layer.

15. The method of claim 14, further comprising:
testing the buffer layer to determine whether the buffer layer is within the desired parameters;
removing at least a portion of the buffer layer if the buffer layer is not within the desired parameters; and
depositing an additional buffer layer to replace the removed portion of the buffer layer.

16. The method of claim 14, wherein the buffer layer comprises GaN or AlN.

17. A method for fabricating a compound nitride semiconductor structure within desired parameters, comprising:
depositing a first GaN layer over the one or more substrates within the first processing chamber;
testing the first GaN layer within the first processing chamber to determine whether the first GaN layer is within the desired parameters;
removing at least a portion of the first GaN layer if the first GaN layer is not within the desired parameters;
depositing an additional first GaN layer to replace the removed portion of the first GaN layer within the first processing chamber;
depositing an InGaN layer over the one or more substrates within a second processing chamber;
testing the InGaN layer within the second processing chamber to determine if the second layer is within the desired parameters;
removing at least a portion of the InGaN layer if the InGaN layer is not within the desired parameters; and
depositing an additional InGaN layer to replace the removed portion of the InGaN layer within the second processing chamber.

18. The method of claim 17, further comprising:
depositing a p-AlGaN layer over the one or more substrates within a third processing chamber;
testing the p-AlGaN layer within the third processing chamber to determine whether the p-AlGaN layer is within the desired parameters;
removing at least a portion of the p-AlGaN layer if the p-AlGaN layer is not within the desired parameters; and
depositing an additional p-AlGaN layer to replace the removed portion of the p-AlGaN layer within the third processing chamber.

19. The method of claim 18, further comprising:
depositing a second GaN layer over the one or more substrates within the third processing chamber;
testing the second GaN layer within the third processing chamber to determine whether the second GaN layer is within desired parameters;
removing at least a portion of the second GaN layer if the second GaN layer is not within the desired parameters; and
depositing an additional second GaN layer to replace the removed portion of the GaN layer within the third processing chamber.

20. An apparatus for fabricating a compound nitride semiconductor structure, comprising:
a processing chamber, comprising:
a chamber body enclosing a processing volume;
a substrate support for supporting one or more substrates proximate the processing volume;
a precursor source for depositing at least one layer on the one or more substrates; and
an etching source for removing defective portions of the at least one layer;
at least one metrology tool for detecting the defective portions of the at least one layer; and
a system controller configured to receive data from the at least one metrology tool, control the etching source to remove the defective portions of the at least one layer, and control the precursor source for depositing an additional layer to replace the removed portions of the at least one layer.
